(19) United States
(12) Patent Application Publication
(10) Pub. No.: US 2022/0013446 A1
(43) Pub. Date: Jan. 13, 2022

(54) High Temperature Barrier Film For Molten Wafer Infusion

(71) Applicants: Menlo Microsystems, Inc., Irvine, CA (US); Corning Incorporated, Corning, NY (US)

(72) Inventors: Jeff S. Baloun, Clemente, CA (US); Willibrordus Gerardus Maria van den Hoek, Saratoga, CA (US)

(21) Appl. No.: 16/922,220

(22) Filed: Jul. 7, 2020

(51) Int. Cl. H01L 23/498; H01L 23/532; H01L 21/768

(52) U.S. Cl. CPC H01L 23/49827; H01L 23/53223; H01L 21/76879; H01L 21/76802; H01L 21/76843; H01L 23/53266

(57) ABSTRACT

A metallized via structure may comprise a via hole, a barrier layer deposited within the via hole, and a metallic plug disposed within the via hole. The via hole may be formed in a device package, and the via hole may be defined by at least one interior wall of the device package. The barrier layer may be disposed upon the at least one interior wall to form a barrier layer lined via hole. The metallic plug may be disposed within the barrier lined via hole by pressurized injection of a molten metal, such that the barrier layer is situated between the metallic plug and the at least one interior wall. The barrier layer may be situated to prevent the metallic plug from contacting the interior wall.

### BACKGROUND

Certain devices, such as switches, may not operate reliably and consistently when exposed to uncontrolled operational environmental conditions. For example, moisture and contamination could cause an increase in early device failures. Accordingly, it is common practice to contain such devices within a protective package, which, at least to some extent, separates an internal device environment from an external environment. Electrical connections, which electrically couple the device to components in the external environment, must pass from the external environment into the device environment and to the device. Device packages may use a through-package via, which is a shaped void in the package walls, to convey a conductor through the package from the external environment to the device environment. When the package is made of glass (e.g., fused SiO₂), the via may be referred to as a through-glass via (TGV).

Such TGVs need to be metallized to implement a hermetic seal at the TGV, while facilitating an electrically conductive path through the package. Aluminum (Al) may be used to metalize a TGV, as disclosed in U.S. Pat. No. 8,242,382, in which molten aluminum is pressurized to flow into the via. A disadvantage of using Al to metalize a TGV, particularly when the package hosting the TGV is a material such as fused SiO₂, is that the molten aluminum may interact with the fused SiO₂ when the aluminum contacts the fused SiO₂ at the TGV walls, causing the overall fused SiO₂ package to become brittle and thus easily damaged. Certain operations, such a chemical-mechanical planarization (CMP), may fracture or otherwise damage altered package material.

### SUMMARY

A through-glass via (TGV) may be formed in a wall of a device package to allow access to components within the package from outside of the package. The TGV may be metallized to facilitate communication of electrical signals through the TGV, while maintaining a hermetic seal at the TGV. The described embodiments are directed to implementing a barrier between (i) a metal plug disposed within a TGV of a device package and (ii) the walls of the TGV. The barrier may be configured to prevent the metal plug from direct contact with the package material in which the TGV resides, thereby preventing an interaction between the aluminum and the device package material.

The described embodiments are directed to processes that introduce molten metal (such as aluminum) into via holes of device package materials. Such device package materials therefore should be survivable at the temperatures of the molten metals (e.g., up to 1,100° C.). Semiconductor materials (e.g., silicon wafers) would not survive such molten metal temperatures, so the molten metal barrier layers of the described embodiments are not used in typical semiconductor processing environments.

In one aspect, the invention may be a metallized via structure, comprising a via hole formed through a substrate. The via hole may be defined by at least one interior wall of the substrate. The metallized via structure may further comprise a barrier layer disposed upon the at least one interior wall to form a barrier layer lined via hole, and a metallic plug disposed within the barrier layer lined via hole by pressurized injection of molten metal. The barrier layer may be situated between the metallic plug and the at least one interior wall. The barrier layer configured to prevent the metallic plug from contacting the interior wall. The barrier layer and the plug together seal the via hole to prevent passage of substances through the substrate at the location of the via hole.

The barrier layer may comprise silicon nitride (Si_{X}N_{Y}H_{Z}). In other embodiments, the barrier layer may comprise a material selected from silicon nitride (Si_{X}N_{Y}H_{Z}), silicon carbide (SiC), titanium disilicide (TiSi₂), tungsten disilicide (WSi₂), tungsten (W), aluminum nitride (AlN), aluminum oxide (Al₂O₃), carbon (C), titanium nitride (TiN), titanium tungsten, zirconia (ZrO₂), yttria (Y₂O₃), and combinations thereof.

The barrier layer may be disposed upon the at least one interior wall using a conformal film deposition procedure. The conformal film deposition procedure comprises one of low pressure chemical vapor deposition (LPCVD), plasma enhanced chemical vapor deposition (PECVD), metalorganic chemical vapor deposition (MOCVD), or atomic layer deposition (ALD).

The metallic plug may comprise a metal selected from aluminum (Al), gold (Au), silver (Ag), copper (Cu), tin (Sn), lead (Pb), magnesium (Mg), and alloys thereof. The metallic plug disposed within the barrier layer lined via hole may be formed by melting the metal to form molten metal, evacuating the barrier layer lined via hole, and injecting the molten metal into the barrier layer lined via hole. The molten metal may be injected into the barrier layer lined hole under pressure. The molten metal may have a melting point that is between 600° C. and 1,100° C.

In another aspect, the invention may be a method of fabricating a metalized via structure, comprising forming a via hole in a substrate. The via hole may be defined by at least one interior wall of the substrate. The method may further comprise disposing a barrier layer upon the at least one interior wall to form a barrier layer lined via hole, and disposing a metallic plug within the barrier layer lined via hole. The barrier layer may be situated between the metallic plug and the at least one interior wall. The barrier layer may be configured to prevent the metallic plug from contacting the interior wall.

The method may further comprise using silicon nitride to form the barrier layer. The method may further comprise using a material selected from silicon nitride (Si_{X}N_{Y}H_{Z}), silicon carbide (SiC), titanium disilicide (TiSi₂), tungsten disilicide (WSi₂), tungsten (W), aluminum nitride (AlN), aluminum oxide (Al₂O₃), carbon (C), titanium nitride (TiN), titanium tungsten, zirconia (ZrO₂), yttria (Y₂O₃), and combinations thereof, to form the barrier layer. The method may further comprise disposing the barrier layer upon the at least one interior wall using a conformal film deposition procedure. The method may further comprise using a conformal film deposition procedure comprises one of low pressure chemical vapor deposition (LPCVD), plasma enhanced chemical vapor deposition (PECVD), metalorganic chemical vapor deposition (MOCVD), or atomic layer deposition (ALD).

In another aspect, the invention may comprise a through-glass via (TGV) structure, comprising a via hole formed in a glass wall. The via hole may be defined by at least one interior surface of the glass wall. The TGV structure may further comprise a barrier layer disposed upon the at least one interior wall to form a barrier layer lined via hole, and a metallic plug disposed within the barrier layer lined via hole. The barrier layer may be situated between the metallic plug and the at least one interior wall.

The barrier layer may comprise silicon nitride (SiN). The barrier layer may comprise a material selected from silicon nitride (Si_{X}N_{Y}H_{Z}), silicon carbide (SiC), titanium disilicide (TISi₂), tungsten disilicide (WSi₂), tungsten (W), aluminum nitride (AlN), aluminum oxide (Al₂O₃), carbon (C), titanium nitride (TiN), titanium tungsten (TiW), zirconia (ZrO₂), yttria (Y₂O₃), and combinations thereof. The barrier layer may be disposed upon the at least one interior wall using a conformal film deposition procedure. The conformal film deposition procedure may comprise one of low pressure chemical vapor deposition (LPCVD), plasma enhanced chemical vapor deposition (PECVD), metalorganic chemical vapor deposition (MOCVD), or atomic layer deposition (ALD). The metallic plug may comprise a metal selected from aluminum (Al), gold (Au), silver (Ag), copper (Cu), tin (Sn), lead (Pb), magnesium (Mg), and alloys thereof.

### BRIEF DESCRIPTION OF THE DRAWINGS

The foregoing will be apparent from the following more particular description of example embodiments, as illustrated in the accompanying drawings in which like reference characters refer to the same parts throughout the different views. The drawings are not necessarily to scale, emphasis instead being placed upon illustrating embodiments.

FIG. 1A shows a substrate upon which a device may be constructed.

FIG. 1B shows a cap that may be bonded to the substrate.

FIG. 1C shows a via that may be formed through the cap.

FIG. 1D shows a via filled with a metal plug.

FIG. 2A shows a cap substrate in its initial state, according to the invention.

FIG. 2B shows a void formed in the cap substrate, according to the invention.

FIG. 2C shows a barrier layer deposited on the cap substrate, according to the invention.

FIG. 2D shows a layer of aluminum disposed on the top and bottom of the cap substrate, and within the via, with the barrier layer separating the aluminum and the cap substrate, according to the invention.

FIG. 2E shows the result of the layer of aluminum removed from the top and bottom surfaces of the cap substrate, leaving the barrier-lined via filled with aluminum, according to the invention.

FIG. 2F shows portions of the cap substrates removed to form one or more cavities, according to the invention.

FIG. 2G shows a device on a device substrate, according to the invention.

FIG. 2H shows the cap substrate bonded to the device substrate to form a hermetically-sealed package.

FIG. 2I shows a top view of the cap substrate, according to the invention.

FIG. 3 shows a procedure for implementing the barrier layer shown in FIGS. 2A, 2B, and 2C, according to the invention.

### DETAILED DESCRIPTION

A description of example embodiments follows.

The teachings of all patents, published applications and references cited herein are incorporated by reference in their entirety.

The described embodiments are directed to a barrier film, integrated with a through-glass via (TGV), to reduce or prevent temperature-driven material interactions between (i) the material in which the TGV is formed (e.g., TGV substrate material such as SiO₂ or quartz), and (ii) a metal disposed into the TGV. It is desirable to prevent such temperature-driven material interactions because the interactions may cause local and global changes to the mechanical properties of the device package material. As a specific example, when molten aluminum is flowed into a TGV formed in a fused silica (SiO₂) substrate, the molten aluminum may diffuse into and/or react with the SiO₂ substrate structure, which may cause the substrate surface to become brittle. Subsequent process steps required for fabrication, such as chemical-mechanical planarization (CMP), may not be possible without causing damage due to the increased brittleness of the substrate.

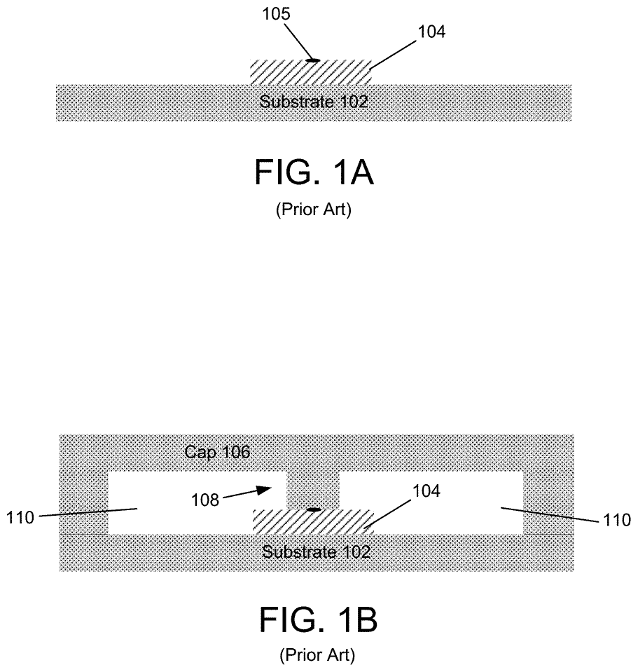

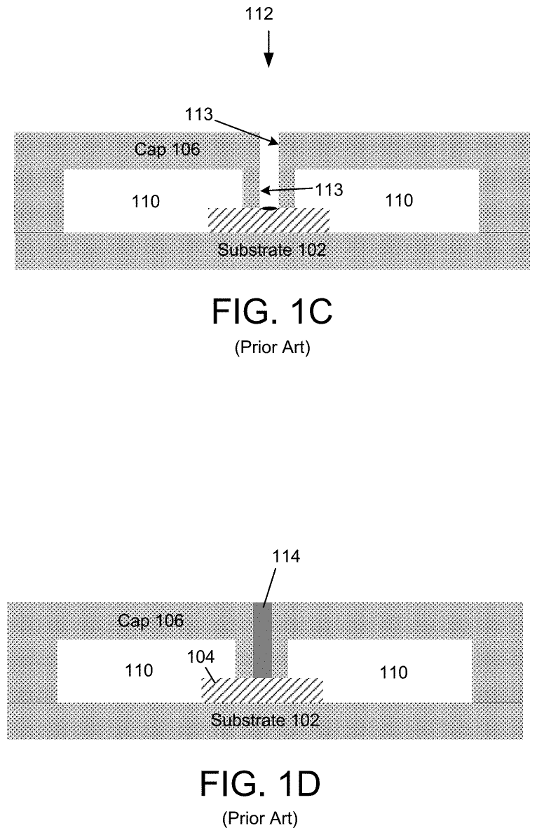

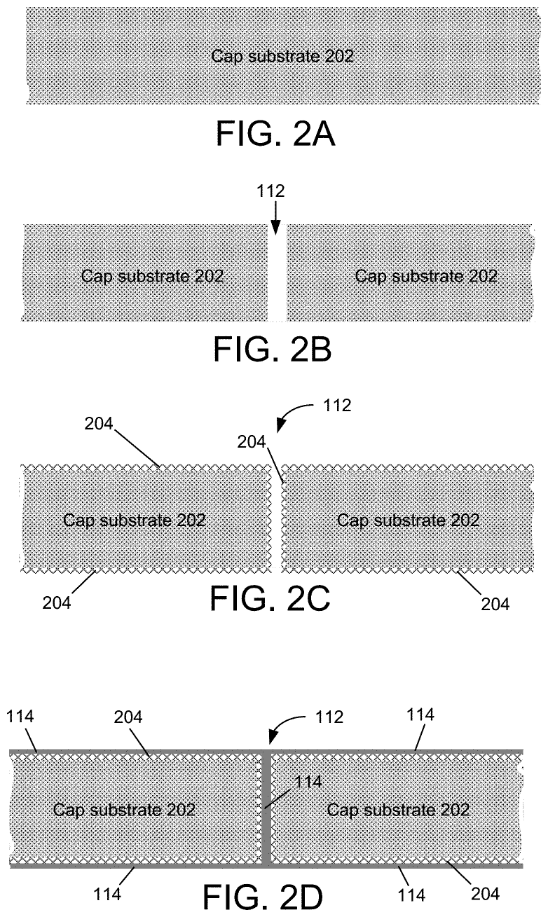

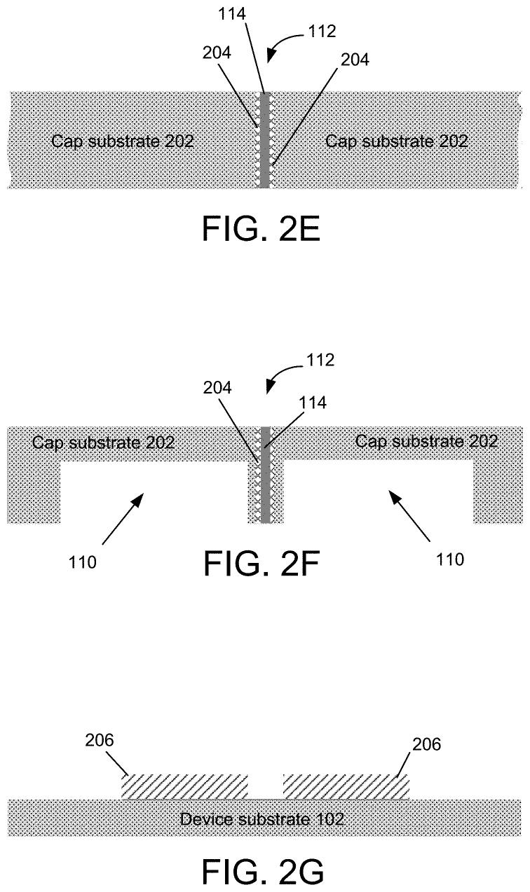

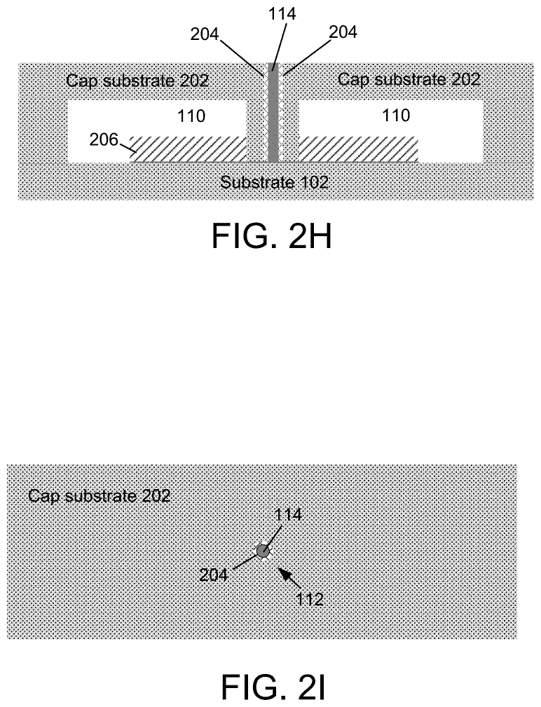

FIGS. 1A-1D provide several sectional views of an example through-glass via (TGV) arrangement to which a barrier film may be applied, according to the described embodiments. FIGS. 2A, 2B, and 2C illustrate a barrier layer disposed in the TGV according to the invention. Although these example embodiments show a cylindrical TGV with a circular cross section, other TGV shapes may alternatively be used. Further, the example embodiments are presented for descriptive purposes, and are not intended to be drawn to scale.

FIG. 1A shows a substrate 102 upon which a device 104 may be constructed. In the example embodiment, the substrate 102 is an insulating substrate such as SiO₂, although other materials, insulating and non-insulating, may alternatively be used. The device 104 may comprise one or more electrical ports 105 configured to receive and/or produce an electrical signal.

FIG. 1B shows a cap 106 that may be bonded to the substrate 104, thereby forming a sealed cavity 110 that encloses the device 104 and isolates the device 104 from the environment outside of the device package formed by the substrate 102 and cap 106. The cap 106 may include a constituent pillar 108 that extends to the device 104. The cap 106 may be an insulating substrate such as SiO₂, although other insulating materials may alternatively be used.

A void or via 112 may be formed through the cap substrate 106 and its pillar 108, as shown in FIG. 1C. The via 112 is defined by interior wall(s) 113 of the cap 106. In an example embodiment, the via 112 may be cylindrical, so that the wall 113 is one continuous surface. In other embodiments, however, the via 112 may be characterized by other shapes and wall profiles. The cap 106 in the example embodiment may be fused SiO₂, so the via 112 may be referred to herein as a through-glass via (TGV). To provide an electrical path from outside of the cap 106 to the device port 105, and to hermetically seal the TGV 112, the TGV 112 may be filled with a metallic plug 114, as shown in FIG. 1D. In the example embodiment, the metallic plug 114 comprises aluminum, although for alternative embodiments the metallic plug 114 may comprise other electrically conductive metals having a melting point that is less than the melting point of the substrate (1100° C. in the case of SiO₂), such as gold (Au), silver (Ag), copper (Cu), tin (Sn), lead (Pb), magnesium (Mg), and alloys thereof. One way of disposing the aluminum plug 114 into the TGV 112 is disclosed in U.S. Pat. No. 8,242,382, which describes molten aluminum that is pressurized to cause the molten aluminum to flow into the TGV. When, however, the molten aluminum contacts the inner walls of the TGV 112, the aluminum may interact with the fused SiO₂ of the cap 106, thereby changing the character of the cap 106, causing it to become brittle and/or causing cracks at the surface of the cap substrate.

FIGS. 2A through 2I show depictions associated with an example procedure for creating a barrier-lined TGV in an insulating substrate. FIGS. 2A through 2H are cut-away drawings, sectioned through a vertical plane of the substrate, so that the barrier-lined via can be seen. In this example embodiment, the substrate is processed to fabricate a cap assembly that is configured to hermetically cover a device substrate, as was illustrated in FIGS. 1A-1D. The cap substrate 202 is shown in its initial state in FIG. 2A. In this view, only a segment of the entire substrate is shown—the far left and right portions are shown as a broken line to indicate the substrate extends further in both directions.

A void 112 may be formed in the cap substrate 202, as shown in FIG. 2B. A barrier layer 204 may be deposited, as shown in FIG. 2C, using a conformal film deposition procedure such as low pressure chemical vapor deposition (LPCVD), plasma enhanced chemical vapor deposition (PECVD), metalorganic chemical vapor deposition (MOCVD), and atomic layer deposition (ALD), although other conformal film deposition procedures known in the art may alternatively be used. During this barrier layer deposition procedure, the barrier layer 204 is deposited on the interior walls of the void 112, as well as the outer surfaces (top, bottom, and edges) of the substrate. FIG. 2C does not show the barrier layer 204 on the left and right edges because, as indicated above with respect to FIG. 2A, the FIGS. 2A through 2E only show a partial segment of the entire substrate 202. It should be understood, however, that for the example embodiment, the barrier layer may be disposed on all exterior portions of the substrate 202, as well as within the via 112, to maintain a complete barrier between the aluminum 114 and the substrate 202.

As shown in FIG. 2D, once molten aluminum 114 is flowed about the cap substrate 202, a layer of aluminum 114 is disposed on the top and bottom of the cap substrate 202, and within the via 112, with the barrier layer 202 separating the aluminum and the substrate 202. A chemical-mechanical planarization (CMP) procedure (or other planarization procedure known in the art) may be used to remove the aluminum 114 and barrier layer 204 from the top and bottom of the cap substrate 202, resulting in the aluminum-filled via as shown in FIG. 2E.

Using a subtractive procedure (e.g., wet etching, although other such techniques known in the art may alternatively be used), portions of the cap substrate 202 may be removed to form the cavities 110, as shown in FIG. 2F. The resulting cap shown in FIG. 2F may be bonded to the device substrate 102 (which is shown in FIG. 2G), to produce the resulting hermetically-sealed package shown in FIG. 2H. The aluminum 114 provides electrical conductivity from the device 206 to components external to the device package. The barrier layer 204 separates the aluminum 114 within the via 112 from the constituent material of the cap substrate 202, thereby preventing the aluminum 114 from being in contact with the cap 202 and preventing an interaction between the aluminum 114 and the cap substrate 202.

FIG. 2I shows a top view of the cap substrate 202. In this example embodiment the TGV 112 has a round cross section, although in alternative embodiments the TGV may have different cross-sectional shapes. As shown in the top view of the cap of FIG. 2C, the barrier layer 204 forms a hollow cylinder around the aluminum 114, which completely separates the aluminum 114 from the cap substrate 202.

In general, the barrier layer 204 comprises a material that may prevent material of the metal fill 114 from propagating into the constituent material of the cap 106, and can do so at temperatures associated with the melting point of the constituent material of the metallic plug 114 (e.g., molten aluminum). The barrier layer 204, once formed on the walls 113 of the via hole 112, presents a barrier between the metal fill 114 and the cap substrate 202. In an example embodiment, the barrier layer 204 may comprise silicon nitride (Si_{X}N_{Y}H_{Z}, where X, Y, and Z are real numbers), although in alternative embodiments the barrier layer may comprise materials such as silicon carbide (SiC), titanium disilicide (TiSi₂), tungsten disilicide (WSi₂), tungsten (W), aluminum nitride (AlN), aluminum oxide (Al₂O₃), carbon (C), titanium nitride (TiN), titanium tungsten (TiW, although other ratios of Ti and W may alternatively be used), zirconia (ZrO₂), and yttria (Y₂O₃), among others, and combinations thereof.

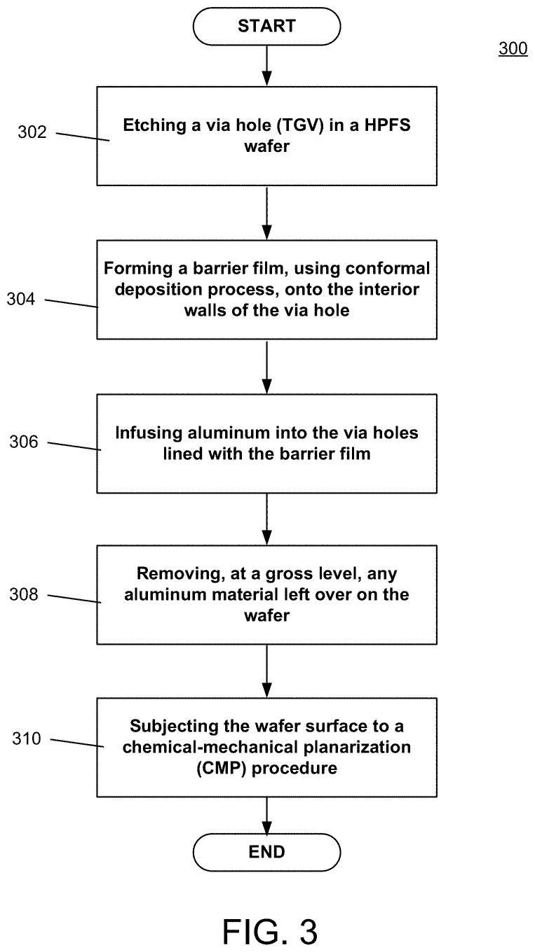

An example embodiment of a procedure 300 associated with the described embodiments is shown in FIG. 3. The procedure 300 may start by etching 302 a via hole (TGV) in a high polished fused silica (HPFS) wafer, the melting point of which is well above the melting point of aluminum. For alternative embodiments, the wafer may comprise quartz or other such material.

The procedure 300 may further comprise forming 304 a barrier film onto the interior walls of the TGV, using, for example, a conformal deposition process. The deposition process may also form a barrier film on the top, bottom, and edge surfaces of the TGV substrate, thereby establishing a barrier about the substrate to reduce or prevent undesirable interaction between the substrate and other materials (e.g., aluminum or other metals). In the example embodiment, the barrier film is silicon nitride (Si_{X}N_{Y}H_{Z}), although different barrier film materials as described herein may alternatively be used in other embodiments.

The procedure 300 may further comprise infusing 306 aluminum into the via holes lined with the barrier film, although other metals as described herein may alternatively be infused. In an example embodiment, the infusing 306 may be accomplished by placing the HPFS wafer into a carbon mold (e.g., a cavity form that is configured to accept the form factor of the wafer), closing carbon mold, evacuating the mold, pouring molten aluminum into the mold, then pressurizing the mold so that the molten aluminum flows completely into the via holes. The procedure 300 may further include opening the mold and removing 308, at a gross level, any aluminum material left over on the wafer (such left-over material may be referred to as “flash”). Once the flash is removed from the wafer at a gross level, the process 300 continues by subjecting 310 the wafer surface to a chemical-mechanical planarization (CMP) procedure to remove, at a fine level, any undesirable materials remaining on the wafer.

While example embodiments have been particularly shown and described, it will be understood by those skilled in the art that various changes in form and details may be made therein without departing from the scope of the embodiments encompassed by the appended claims.

1. A metallized via structure, comprising:
a via hole formed through a substrate, the via hole defined by at least one interior wall of the substrate;
a barrier layer disposed upon the at least one interior wall to form a barrier layer lined via hole; and
a metallic plug disposed within the barrier layer lined via hole by pressurized injection of molten metal, such that the barrier layer is situated between the metallic plug and the at least one interior wall, the barrier layer configured to prevent the metallic plug from contacting the interior wall.

2. The metallized via structure of claim 1, wherein the barrier layer comprises silicon nitride (Si_{X}N_{Y}H_{Z}).

3. The metalized via structure of claim 1, wherein the barrier layer comprises a material selected from silicon nitride (Si_{X}N_{Y}H_{Z}), silicon carbide (SiC), titanium disilicide (TiSi₂), tungsten disilicide (WSi₂), tungsten (W), aluminum nitride (AlN), aluminum oxide (Al₂O₃), carbon (C), titanium nitride (TiN), titanium tungsten, zirconia (ZrO₂), yttria (Y₂O₃), and combinations thereof.

4. The metalized via structure of claim 1, wherein the barrier layer is disposed upon the at least one interior wall using a conformal film deposition procedure.

5. The metalized via structure of claim 4, wherein the conformal film deposition procedure comprises one of low pressure chemical vapor deposition (LPCVD), plasma enhanced chemical vapor deposition (PECVD), metalorganic chemical vapor deposition (MOCVD), or atomic layer deposition (ALD).

6. The metalized via structure of claim 21, wherein the metallic plug comprises a metal selected from aluminum (Al), gold (Au), silver (Ag), copper (Cu), tin (Sn), lead (Pb), magnesium (Mg), and alloys thereof.

7. The metalized via structure of claim 1, wherein the metallic plug disposed within the barrier layer lined via hole is formed by melting the metal to form molten metal, evacuating the barrier layer lined via hole, and injecting the molten metal into the barrier layer lined via hole.

8. The metalized via structure of claim 7, wherein the molten metal is injected into the barrier layer lined hole under pressure.

9. The metalized via structure of claim 1, the molten metal having a melting point that is between 600° C. and 1,100° C.

10. A method of fabricating a metalized via structure, comprising:
forming a via hole in a substrate, the via hole defined by at least one interior wall of the substrate;
disposing a barrier layer upon the at least one interior wall to form a barrier layer lined via hole; and
disposing a metallic plug within the barrier layer lined via hole such that the barrier layer is situated between the metallic plug and the at least one interior wall, the barrier layer configured to prevent the metallic plug from contacting the interior wall.

11. The method of claim 10, further comprising using silicon nitride to form the barrier layer.

12. The method of claim 10, further comprising using a material selected from silicon nitride (Si_{X}N_{Y}H_{Z}), silicon carbide (SiC), titanium disilicide (TiSi₂), tungsten disilicide (WSi₂), tungsten (W), aluminum nitride (AlN), aluminum oxide (Al₂O₃), carbon (C), titanium nitride (TiN), titanium tungsten, zirconia (ZrO₂), yttria (Y₂O₃), and combinations thereof, to form the barrier layer.

13. The method of claim 10, further comprising disposing the barrier layer upon the at least one interior wall using a conformal film deposition procedure.

14. The method of claim 13, wherein using a conformal film deposition procedure comprises one of low pressure chemical vapor deposition (LPCVD), plasma enhanced chemical vapor deposition (PECVD), metalorganic chemical vapor deposition (MOCVD), or atomic layer deposition (ALD).

15. A through-glass via (TGV) structure, comprising:
a via hole formed in a glass substrate, the via hole defined by at least one interior surface of the glass substrate;
a barrier layer disposed upon the at least one interior wall to form a barrier layer lined via hole; and
a metallic plug disposed within the barrier layer lined via hole by pressurized injection of molten metal, such that the barrier layer is situated between the metallic plug and the at least one interior wall.

16. The TGV structure of claim 15, wherein the barrier layer comprises silicon nitride (Si_{X}N_{Y}H_{Z}).

17. The TGV structure of claim 16, wherein the barrier layer comprises a material selected from silicon nitride (Si_{X}N_{Y}H_{Z}), silicon carbide (SiC), titanium disilicide (TiSi₂), tungsten disilicide (WSi₂), tungsten (W), aluminum nitride (AlN), aluminum oxide (Al₂O₃), carbon (C), titanium nitride (TiN), titanium tungsten (TiW), zirconia (ZrO₂), yttria (Y₂O₃), and combinations thereof.

18. The TGV structure of claim 16, wherein the barrier layer is disposed upon the at least one interior wall using a conformal film deposition procedure.

19. The TGV structure of claim 18, wherein the conformal film deposition procedure comprises one of low pressure chemical vapor deposition (LPCVD), plasma enhanced chemical vapor deposition (PECVD), metalorganic chemical vapor deposition (MOCVD), or atomic layer deposition (ALD).

20. The TGV structure of claim 25, wherein the metallic plug comprises a metal selected from aluminum (Al), gold (Au), silver (Ag), copper (Cu), tin (Sn), lead (Pb), magnesium (Mg), and alloys thereof.

21. The metalized via structure of claim 1, wherein the metallic plug comprises a metal that has a melting point lower than a melting point of the substrate.

22. The metalized via structure of claim 15, wherein the metallic plug disposed within the barrier layer lined via hole is formed by melting the metal to form molten metal, evacuating the barrier layer lined via hole, and injecting the molten metal into the barrier layer lined via hole.

23. The metalized via structure of claim 22, wherein the molten metal is injected into the barrier layer lined hole under pressure.

24. The metalized via structure of claim 15, the molten metal having a melting point that is between 600° C. and 1,100° C.

25. The metalized via structure of claim 15, wherein the metallic plug comprises a metal that has a melting point lower than a melting point of the substrate.
